(19) United States
(12) Patent Application Publication
(10) Pub. No.: US 2006/0043490 A1
(43) Pub. Date: Mar. 2, 2006

(54) Electrostatic discharge (ESD) detection and protection

(75) Inventors: Fred Brauchler, Rowlett, TX (US); Ismail Oguzman, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/146,702

(22) Filed: Jun. 7, 2005

Related U.S. Application Data
(60) Provisional application No. 60/607,161, filed on Sep. 2, 2004.

(51) Int. Cl. H01L 23/62

(52) U.S. Cl. 257/355

(57) ABSTRACT

A system and method are provided for protecting a transistor from electrostatic discharge (ESD) current associated with an ESD event. In one embodiment, a system comprises a detection circuit operative to detect an ESD event and a switch that is operative to hold the transistor in a deactivated state in response to the detection circuit detecting the ESD event. The system further comprises an ESD protection circuit operative to divert the ESD current from flowing through the transistor upon the transistor being held in a deactivated state.

### CROSS REFERENCE TO RELATED APPLICATIONS

The present application claims the benefit of U.S. Provisional Patent Application Ser. No. 60/607,161, filed Sep. 2, 2004, entitled “ESD PROTECTION CELL FOR AN OUTPUT STAGE DEVICE”, and which is incorporated herein by reference.

### TECHNICAL FIELD

This invention relates to electronic circuits, and more specifically to a system and method for detecting electrostatic discharge (ESD) events and protecting circuit components from damage resulting from an ESD event.

### BACKGROUND

Integrated circuits (ICs) can be damaged by electrostatic discharge (ESD) events, in which large currents flow through the device. These ESD events often involve situations where an IC becomes charged and discharges to ground. Additionally, ESD events typically involve discharge of current between one or more pins or pads exposed to the outside of an IC chip. During an ESD event, current may flow through vulnerable circuitry in the IC that may not be designed to carry such currents. The vulnerability of IC chips to ESD events has created an important need for ESD protection circuits.

As a result of the need to protect IC chips from ESD events, ESD protection circuits are often added to the integral design of IC chips, such as RF power amplifiers. Many conventional ESD protection schemes for ICs employ peripheral dedicated circuits to carry the ESD currents from the pin or pad of the device to ground by providing a low impedance path. Thus, an ESD protection circuit requires low impedance for proper ESD protection. In this way, the ESD currents flow through the ESD protection circuitry, rather than through the more vulnerable circuits in the chip. However, it is often necessary for an input or an output device to also have a relatively low impedance path between an input terminal or an output terminal and ground or a positive voltage supply to maintain optimal performance, such that the impedance through the device may be the same as or lower than the impedance of the protection circuitry.

### SUMMARY

One embodiment describes a system for protecting a transistor from electrostatic discharge (ESD) current associated with an ESD event. The system comprises a detection circuit operative to detect an ESD event and a switch operative to hold the transistor in a deactivated state in response to the detection circuit detecting the ESD event. The system further comprises an ESD protection circuit operative to divert the ESD current from flowing through the transistor upon the transistor being held in a deactivated state.

Another embodiment describes a system for protecting a transistor from ESD current associated with an ESD event. The system comprises a means for detecting an ESD event and a means for holding the transistor in a deactivated state in response to detecting the ESD event. The system also comprises a means for diverting the ESD current from flowing through the transistor upon the transistor being held in a deactivated state and a means for returning the system to normal operating conditions after the occurrence of the ESD event.

Another embodiment describes a method for protecting a transistor from ESD current associated with an ESD event. The method comprises detecting an ESD event and holding the transistor in a deactivated state in response to detecting the ESD event. The method also comprises diverting the ESD current from flowing through the transistor upon holding the transistor in a deactivated state.

### BRIEF DESCRIPTION OF THE DRAWINGS

FIG. 1 illustrates an example of a power amplifier circuit including an ESD detection and protection circuit in accordance with an aspect of the invention.

FIG. 2 illustrates another example of a power amplifier circuit including an ESD detection and protection circuit in accordance with an aspect of the invention.

FIG. 3 illustrates yet another example of a power amplifier circuit including an ESD detection and protection circuit in accordance with an aspect of the invention.

FIG. 4 illustrates an example of an input circuit including an ESD detection and protection circuit in accordance with an aspect of the invention.

FIG. 5 illustrates a method for detecting an ESD event and protecting a device from damage resulting from the ESD event in accordance with an aspect of the invention.

### DETAILED DESCRIPTION

The present invention relates to electronic circuits, and more specifically to a system and method for detecting electrostatic discharge (ESD) events and protecting circuit components from damage resulting from an ESD event. An ESD detection and protection circuit is included in a circuit to prevent damage resulting from an ESD event to an input or an output device. The ESD detection and protection circuit detects the occurrence of an ESD event and reacts by increasing a breakdown voltage of the input or output device, such that the impedance of the input or output device is increased relative to the impedance of an ESD protection circuit. The ESD current is diverted from the input or output device and discharged through the ESD protection circuit, thus protecting the device from damage resulting from the ESD event. Furthermore, the ESD detection and protection circuit does not interfere with normal operation of the circuit that it is intended to protect, as the input or output device also provides a low impedance path under normal operation of the circuit.

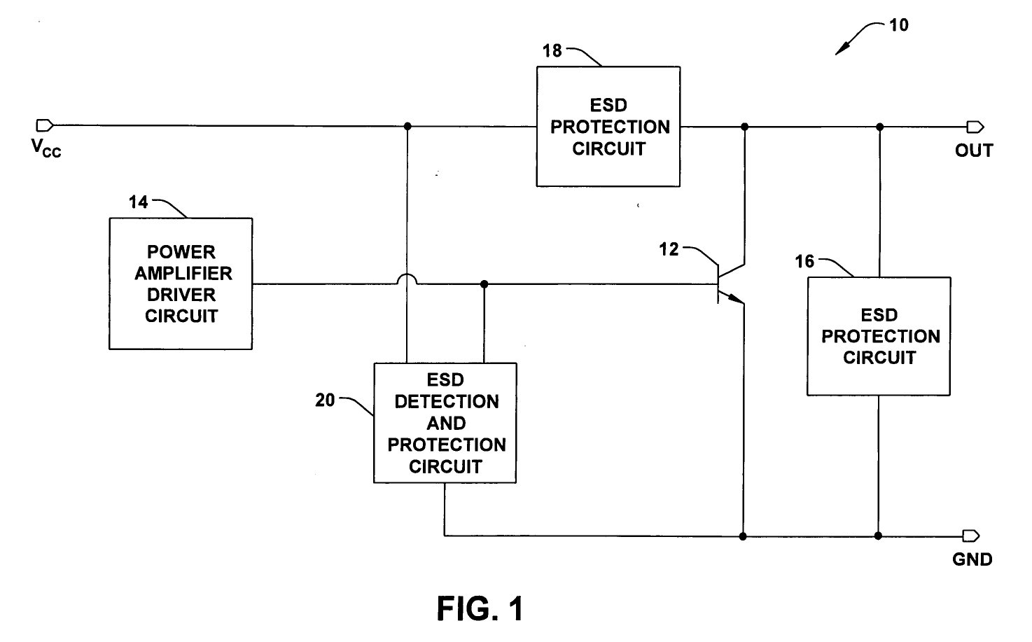

FIG. 1 illustrates an example of a power amplifier circuit 10 that includes an ESD detection and protection circuit 20 in accordance with an aspect of the invention. It is to be understood that the ESD detection and protection circuit 20 is not limited to use in a power amplifier circuit. Other circuits that employ an input or an output device that is desired to be protected from damage resulting from an ESD event can utilize the ESD detection and protection circuit 20 in accordance with an aspect of the invention.

The power amplifier circuit 10 includes an NPN-type output bipolar junction transistor (BJT) 12. In the example of FIG. 1, the output BJT 12 is the device that is desired to be protected from damage resulting from an ESD event. It is to be appreciated that the ESD detection and protection circuit 20 can be employed to protect a variety of different types of transistors. The power amplifier circuit 10 also includes a power amplifier driver circuit 14 that is connected to a base terminal of the output BJT 12, such that the power amplifier driver circuit 14 transmits an input signal amplified by the output BJT 12. The output BJT 12 has a collector terminal that is connected to an output pin OUT, which could be an output pin on an integrated circuit (IC). The output BJT 12 also has an emitter terminal that is connected to a negative voltage supply terminal, demonstrated in the example of FIG. 1 as a ground pin GND, which could be a grounding pin on the IC. In the example of FIG. 1, it is desired to protect the output BJT 12 from damage resulting from a positive ESD strike on the output pin OUT, such that ESD current could flow from the output pin OUT to the ground pin GND through the output BJT 12. Accordingly, the power amplifier circuit 10 also includes a first ESD protection circuit 16 interconnected between the output pin OUT and the ground pin GND, parallel to the output BJT 12. The first ESD protection circuit 16 could be one of a variety of ESD protection circuit types operative to supply a low impedance current path from the output pin OUT to the ground pin GND (e.g., an arrangement of diodes).

The power amplifier circuit 10 also includes a second ESD protection circuit 18 interconnected between a positive voltage supply terminal V_{CC} and the output pin OUT. The positive voltage supply terminal V_{CC} could be an input power voltage pin on the IC. The second ESD protection circuit 18 could be a variety of ESD protection circuit types operative to supply a low impedance current path between the output pin OUT and the positive voltage supply terminal V_{CC} (e.g., an arrangement of diodes). It is to be understood that a variety of additional ESD protection circuits can be included in the power amplifier circuit 10, such as, for example, between the positive voltage supply terminal V_{CC} and the ground pin GND, to ensure additional protection against different combinations of ESD events.

As described above, upon the occurrence of a positive ESD event at the output pin OUT of the power amplifier circuit 10, ESD current will attempt to flow from the output pin OUT to the ground pin GND. If a substantial amount of the ESD current flows through the output BJT 12, the output BJT 12 can be damaged, thus rendering the power amplifier circuit 10 inoperable. The first ESD protection circuit 16 may divert the ESD current away from the output BJT 12, such that a substantial amount of the ESD current flows through the first ESD protection circuit 16 as opposed to the output BJT 12. However, a voltage potential at the base terminal of the output BJT 12 is undefined and can take any arbitrary value, such that the output BJT 12 could be activated at the occurrence of the ESD event. Activation of the output BJT results in a low impedance path from the collector node to the emitter node of the output BJT 12, such that the path from the collector node to the emitter node of the output BJT 12 has a lower impedance than the path through the first ESD protection circuit 16, causing a substantial portion of the ESD current to flow through the output BJT 12. The ESD detection and protection circuit 20 is provided to mitigate this situation, and is interconnected between the positive voltage supply terminal V_{CC}, the ground pin GND, and the base terminal of the output BJT 12.

The ESD detection and protection circuit 20 operates to detect the occurrence of an ESD event and to hold the output BJT 12 in a deactivated state in response to detecting the ESD event. By holding the output BJT 12 in a deactivated state, the output BJT 12 is held at a higher impedance than the first ESD protection circuit 16, such that the ESD current will be diverted from the output BJT 12 and will instead flow through the first ESD protection circuit 16, thus preventing damage to the output BJT 12. For example, upon the occurrence of a positive ESD event at the output pin OUT, the voltage potential of the output pin OUT increases, and thus the voltage potential of the positive voltage supply terminal V_{CC} also increases through the second ESD protection circuit 18. The ESD detection and protection circuit 20 could respond by coupling the base terminal of the output BJT 12 to ground, such as by switching the base terminal to the ground pin GND. The output BJT 12 thus is held in a deactivation state, and therefore has a breakdown voltage that is substantially greater than an activation voltage of the first ESD protection circuit 16, the activation voltage being a voltage potential sufficient to allow current flow through the first ESD protection circuit 16. Accordingly, a substantial amount of the ESD current flows from the output pin OUT to the ground pin GND through the first ESD protection circuit 16, instead of through the higher impedance path of the deactivated output BJT 12.

It is to be understood that, in the example of FIG. 1, the ESD detection and protection circuit 20 need not be connected to the positive voltage supply terminal V_{CC} to detect an ESD event. Instead, the ESD detection and protection circuit 20 could be connected to another node, such as the output pin OUT, which experiences a substantial increase in voltage potential upon the occurrence of an ESD event.

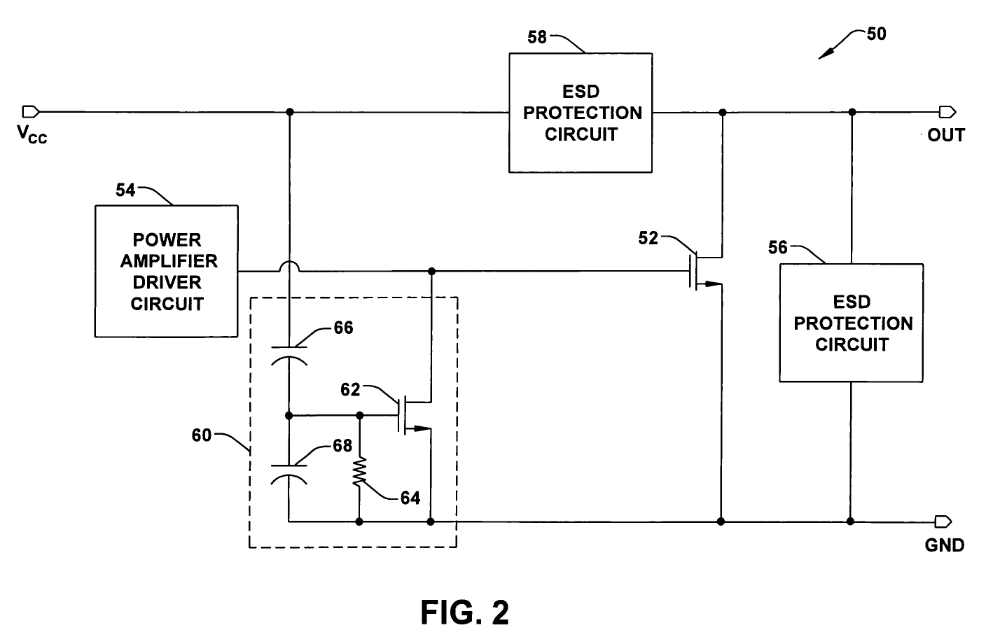

FIG. 2 illustrates another example of a power amplifier circuit 50 that includes an ESD detection and protection circuit 60 in accordance with an aspect of the invention. The power amplifier circuit 50 includes an N-type output FET 52 with a drain terminal connected to an output pin OUT and a source terminal connected to a negative voltage supply terminal, demonstrated in the example of FIG. 2 as a ground pin GND. In the example of FIG. 2, the output FET 52 is the device that is desired to be protected from damage resulting from an ESD event. The power amplifier circuit 50 also includes a power amplifier driver circuit 54, a first ESD protection circuit 56, and a second ESD protection circuit 58, all of which function in substantially the same way as described in the previous example of FIG. 1, and therefore further description will be omitted for the sake of brevity. It is also to be understood that a variety of additional ESD protection circuits can be included in the power amplifier circuit 50, such as, for example, between the positive voltage supply terminal V_{CC} and the ground pin GND, to ensure additional protection against different combinations of ESD events.

Additionally, the power amplifier circuit 50 includes an ESD detection and protection circuit 60 interconnected between a positive voltage supply terminal V_{CC}, the ground pin GND, and a gate terminal of the output FET 52. The ESD detection and protection circuit 60 operates to detect the occurrence of an ESD event and to hold the output FET 52 in a deactivated state in response to detecting the ESD event. By holding the output FET 52 in a deactivated state, the output FET 52 is set to a higher impedance than the first ESD protection circuit 56, such that ESD current will be diverted from the output FET 52 and will instead substantially flow through the first ESD protection circuit 56, thus preventing damage to the output FET 52.

The ESD detection and protection circuit 60 includes an N-type FET 62 that operates as a switch between the gate terminal of the output FET 52 and the ground pin GND. The ESD detection and protection circuit 60 also includes a resistor 64 interconnected between a gate terminal of the N-type FET or switch 62 and the ground pin GND, a capacitor 66 interconnected between the positive voltage supply terminal V_{CC} and the gate terminal of the N-type FET or switch 62, and a capacitor 68 interconnected between the gate terminal of the N-type FET or switch 62 and the ground pin GND. The capacitors 66 and 68 operate as a capacitor divider, such that upon the voltage potential of the positive voltage supply terminal V_{CC} increasing, the voltage potential of the gate terminal of the N-type FET or switch 62 will also increase, but at smaller increments than the positive voltage supply V_{CC}, both relative to the ground pin GND.

Upon the occurrence of a positive ESD event at the output pin OUT, the voltage potential of the output pin OUT increases, and thus the voltage potential of the positive voltage supply terminal V_{CC} also increases through the second ESD protection circuit 58. Due to the capacitor divider arrangement of the capacitors 66 and 68, the voltage potential at the gate terminal of the N-type FET or switch 62 also increases relative to the ground pin GND. The N-type FET or switch 62 thus activates (e.g., closes) and couples the gate terminal of the output FET 52 to the ground pin GND. The gate terminal of the output FET 52 is therefore switched to ground, holding the output FET 52 in a deactivated state. After the output FET 52 is held in a deactivated state, the output FET 52 has a breakdown voltage in the deactivated state that is substantially greater than an activation voltage of the first ESD protection circuit 56, the activation voltage being a voltage potential sufficient to allow current flow through the first ESD protection circuit 56. Accordingly, a substantial amount of the ESD current flows from the output pin OUT to the ground pin GND through the first ESD protection circuit 56, instead of through the higher impedance FET 52. Shortly after the ESD current has substantially dissipated to the ground pin GND, the resistor 64 operates to discharge the capacitor 68, such that the N-type FET or switch 62 eventually deactivates, returning the output FET 52, and thus the power amplifier circuit 50, back to normal operating condition.

It is to be understood that, in the example of FIG. 2, the capacitor 66 need not be connected to the positive voltage supply terminal V_{CC} to detect an ESD event. Instead, the capacitor 66 could be connected to another node, such as the output pin OUT, which experiences a substantial increase in voltage potential upon the occurrence of an ESD event. As an example, the capacitor 66 could be connected to the internal circuitry of the first ESD protection circuit 56, such that the capacitor 66 will detect the increase in voltage potential upon the occurrence of the ESD event, but can be configured so as not to apply an additional load to the output pin OUT.

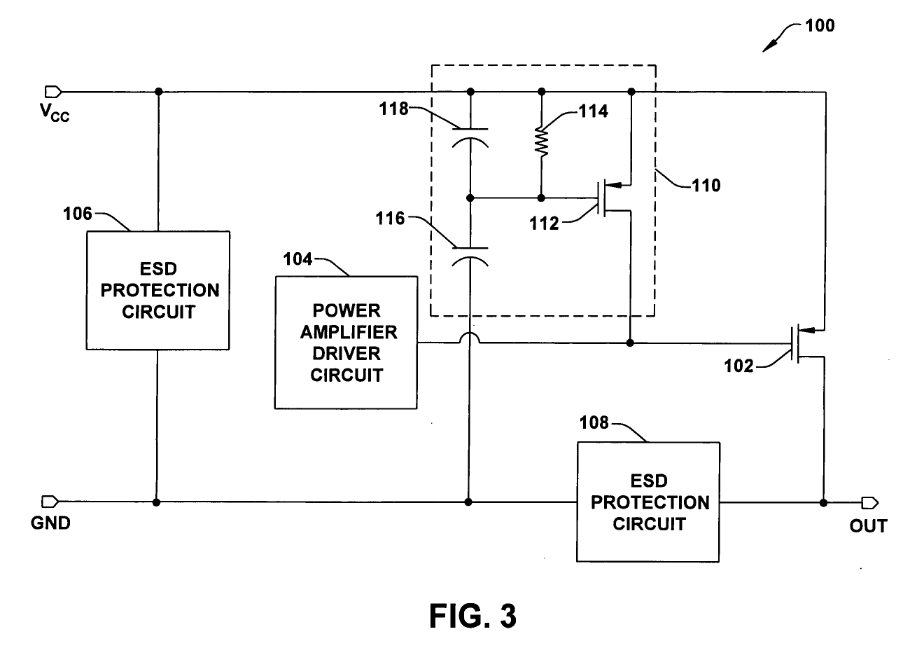

FIG. 3 illustrates yet another example of a power amplifier circuit 100 that includes an ESD detection and protection circuit 110 in accordance with an aspect of the invention. The power amplifier circuit 100 includes a P-type output FET 102 with a drain terminal connected to an output pin OUT and a source terminal connected to a positive voltage supply terminal V_{CC}. In the example of FIG. 3, the output FET 102 is the device that is desired to be protected from damage resulting from an ESD event. The power amplifier circuit 100 also includes a power amplifier driver circuit 104, a first ESD protection circuit 106, and a second ESD protection circuit 108, all of which function in substantially the same way as described in the previous example of FIG. 1, and therefore further description will be omitted for the sake of brevity. As such, a positive ESD event that occurs at the output pin OUT relative to a negative voltage supply terminal, demonstrated in the example of FIG. 1 as a ground pin GND, will simply result in ESD current flow through the second ESD protection circuit 108. However, in the example of FIG. 3, it is desirable to protect the output FET 102 from damage resulting from a positive ESD event that occurs at the positive voltage supply terminal V_{CC} relative to the output pin OUT by diverting the ESD current through the first ESD protection circuit 106 to the ground pin GND, and then subsequently through the second ESD protection circuit 108 to the output pin OUT. It is to be understood that a variety of additional ESD protection circuits can be included in the power amplifier circuit 100, such as, for example, between the source terminal of the output FET and the output pin OUT, to ensure additional protection against different combinations of ESD events. It is to be understood that the following description could apply equally to a power amplifier circuit that includes a PNP-type BJT that is desired to be protected from damage resulting from an ESD event.

The ESD detection and protection circuit 110 is interconnected between a positive voltage supply terminal V_{CC}, the ground pin GND, and a gate terminal of the output FET 102. The ESD detection and protection circuit 110 operates to detect the occurrence of a positive ESD event that occurs between the positive voltage supply terminal V_{CC} and the output pin OUT, and to hold the output FET 102 in a deactivated state in response to detecting the ESD event. By holding the output FET 102 in a deactivated state, the output FET 102 is set to a higher impedance than the path through the first ESD protection circuit 106 and the second ESD protection circuit 108, such that ESD current will be diverted from the output FET 102 and will instead flow through the first ESD protection circuit 106 and the second ESD protection circuit 108, thus preventing damage to the output FET 102.

The ESD detection and protection circuit 110 includes a P-type FET 112 that operates as a switch between the gate terminal of the output FET 102 and the positive voltage supply terminal V_{CC}. The ESD detection and protection circuit 110 also includes a resistor 114 interconnected between a gate terminal of the P-type FET or switch 112 and the positive voltage supply terminal V_{CC}, a capacitor 116 interconnected between the ground pin GND and the gate terminal of the P-type FET or switch 112, and a capacitor 118 interconnected between the gate terminal of the P-type FET or switch 112 and the positive voltage supply terminal V_{CC}. The capacitors 116 and 118 operate as a capacitor divider, such that upon the voltage potential of the positive voltage supply terminal V_{CC} increasing, the voltage potential of the gate terminal of the P-type FET or switch 112 will also increase, but at smaller increments than the positive voltage supply V_{CC}, both relative to the ground pin GND.

Upon the occurrence of a positive ESD event at the positive voltage supply terminal V_{CC}, the voltage potential of the positive voltage supply terminal V_{CC} increases. Due to the capacitor divider arrangement of the capacitors 116 and 118, the capacitor 116 prevents the voltage potential at the gate terminal of the P-type FET or switch 112 from increasing at the same increment as the positive voltage supply terminal V_{CC} relative to the ground pin GND. The P-type FET or switch 112 thus activates (e.g., closes) and connects the gate terminal of the FET 102 to the positive voltage supply terminal V_{CC}. The gate terminal of the FET 102 is therefore coupled to V_{CC}, holding the FET 102 in a deactivated state. The FET 102 has a breakdown voltage in the deactivated state that is substantially greater than an activation voltage of the path through the first ESD protection circuit 106 and the second ESD protection circuit 108, the activation voltage being a voltage potential sufficient to allow current flow through the path through the first ESD protection circuit 106 and the second ESD protection circuit 108. Accordingly, a substantial amount of the ESD current flows from the positive voltage supply terminal V_{CC} to the ground pin GND through the first ESD protection circuit 106 and then to the output pin OUT through the second ESD protection circuit 108, instead of through the higher impedance output FET 102 to the output pin OUT. Shortly after the ESD current has substantially dissipated, the resistor 114 operates to discharge the capacitor 118, such that the P-type FET or switch 112 eventually deactivates, returning the output FET 102, and thus the power amplifier circuit 100, back to normal operating conditions.

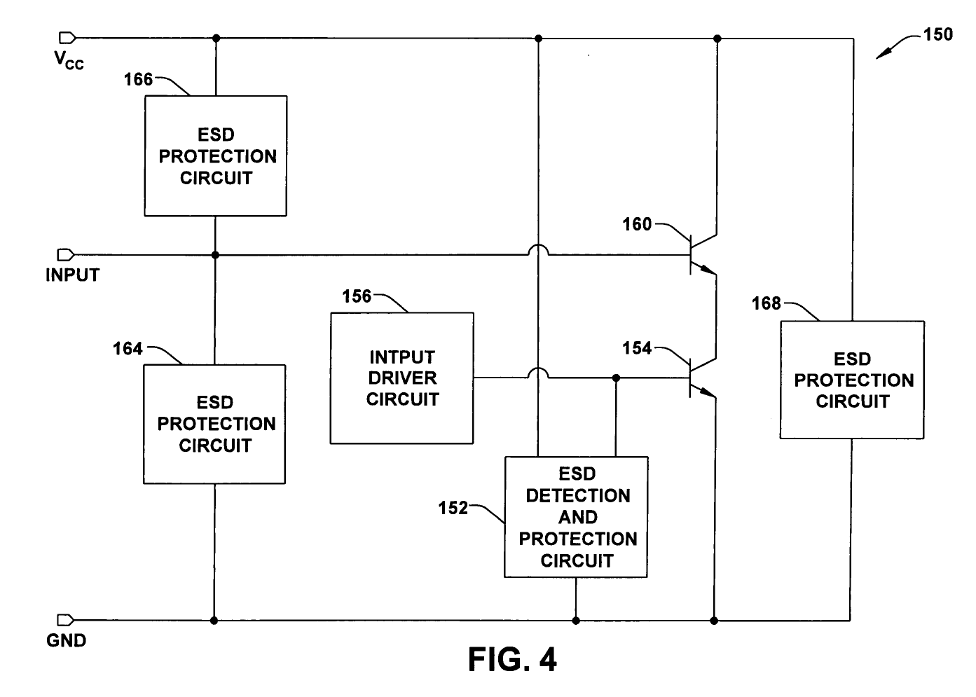

FIG. 4 illustrates an example of an input circuit 150 that includes an ESD detection and protection circuit 152 in accordance with an aspect of the invention. The input circuit 150 includes a first NPN-type input bipolar junction transistor (BJT) 154. In the example of FIG. 4, the first input BJT 154 is the device that is desired to be protected from damage resulting from an ESD event. It is to be appreciated that the ESD detection and protection circuit 152 can be employed to protect a variety of different types of transistors. The input circuit 150 also includes an input bias circuit 156 that is connected to a base terminal of the first input BJT 154, such that the input bias circuit 156 sets a bias for the first input BJT 154. The first input BJT 154 has an emitter terminal that is connected to a negative voltage supply terminal, demonstrated in the example of FIG. 4 as a ground pin GND, which could be a grounding pin on an IC. The input circuit 150 also includes a second input BJT 160. The second BJT 160 has a base terminal that is connected to an input pin INPUT, which could be an input pin on the IC. The second BJT 160 also has a collector terminal that is connected to a positive voltage supply V_{CC}, and an emitter terminal that is connected to a collector terminal of the BJT 158. The positive voltage supply terminal V_{CC} could be an input power voltage pin on the IC. A load circuit (not shown) which the input circuit 150 activates could be located, for example, at the emitter terminal of the second BJT 160.

In the example of FIG. 4, it is desired to protect the first input BJT 154 from damage resulting from a positive ESD strike on the input pin INPUT, such that ESD current could flow from the input pin INPUT to the ground pin GND through the first input BJT 154. Accordingly, the input circuit 150 also includes a first ESD protection circuit 164 interconnected between the input pin INPUT and the ground pin GND, parallel to the first input BJT 154. The first ESD protection circuit 164 could be one of a variety of ESD protection circuit types operative to supply a low impedance current path from the input pin INPUT to the ground pin GND (e.g., an arrangement of diodes).

The input circuit 150 also includes a second ESD protection circuit 166 interconnected between the positive voltage supply terminal V_{CC} and the input pin INPUT, and a third ESD protection circuit 168 interconnected between the positive voltage supply terminal V_{CC} and the ground pin GND. The second ESD protection circuit 166 and the third ESD protection circuit 168 could each be one of a variety of ESD protection circuit types operative to supply a low impedance current path (e.g., an arrangement of diodes). For example, the second ESD protection circuit 166 could supply a low impedance path between the positive voltage supply terminal V_{CC} and the input pin INPUT in the event of a positive ESD strike from the positive voltage supply terminal V_{CC} and the input pin INPUT. Additionally, the third ESD protection circuit 168 could supply a low impedance path between the positive voltage supply terminal V_{CC} and the ground pin GND in the event of a positive ESD strike from the positive voltage supply terminal V_{CC} and the ground pin GND.

As described above, upon the occurrence of a positive ESD event at the input pin INPUT of the input circuit 150, ESD current will attempt to flow from the input pin INPUT to the ground pin GND. If a substantial amount of the ESD current flows through the first input BJT 154 via the base-emitter junction of the second input BJT 160, both the first input BJT 154 and/or the second input BJT 160 could be damaged, thus rendering the input circuit 150 inoperable. The first ESD protection circuit 164 may divert the ESD current away from the second input BJT 160 and the first input BJT 154, such that a substantial amount of the ESD current flows through the first ESD protection circuit 164 as opposed to through the first input BJT 154. However, a voltage potential at the base terminal of the first input BJT 154 could be floating, such that the first input BJT 154 is activated or almost activated at the occurrence of the ESD event. This could result in a low impedance path from the collector node to the emitter node of the first input BJT 154, such that the path through the base-emitter junction of the second input BJT 160 and through the collector node to the emitter node of the first input BJT 154 has a lower impedance than the path through the first ESD protection circuit 164, causing a substantial portion of the ESD current to flow through the first input BJT 154. The ESD detection and protection circuit 152 is provided to mitigate this situation, and is interconnected between the positive voltage supply terminal V_{CC}, the ground pin GND, and the base terminal of the first input BJT 154.

The ESD detection and protection circuit 152 operates to detect the occurrence of an ESD event and to hold the first input BJT 154 in a deactivated state in response to detecting the ESD event. By holding the first input BJT 154 in a deactivated state, the first input BJT 154 is held at a higher impedance than the first ESD protection circuit 164, such that the ESD current will be diverted from the first input BJT 154 and will instead flow through the first ESD protection circuit 164, thus preventing damage to the first input BJT 154. For example, upon the occurrence of a positive ESD event at the input pin INPUT, the voltage potential of the input pin INPUT increases, and thus the voltage potential of the positive voltage supply terminal V_{CC} also increases through the second ESD protection circuit 166. The ESD detection and protection circuit 152 could respond by coupling the base terminal of the first input BJT 154 to ground, such as by switching the base terminal to the ground pin GND. The first input BJT 154 thus is held in a deactivation state, and therefore has a breakdown voltage that is substantially greater than an activation voltage of the first ESD protection circuit 164, the activation voltage being a voltage potential sufficient to allow current flow through the first ESD protection circuit 164. Accordingly, a substantial amount of the ESD current flows from the input pin INPUT to the ground pin GND through the first ESD protection circuit 164, instead of through the higher impedance path of the first input BJT 154.

It is to be understood that, in the example of FIG. 4, the ESD detection and protection circuit 152 need not be connected to the positive voltage supply terminal V_{CC} to detect an ESD event. Instead, the ESD detection and protection circuit 152 could be connected to another node, such as the input pin INPUT, which experiences a substantial increase in voltage potential upon the occurrence of an ESD event. It is to be further understood that the input circuit 150 is but one example of an input circuit that can be protected from ESD strikes using the ESD detection and protection circuit 152 in accordance with an aspect of the invention. For example, the input circuit 150 could include a differential input in place of the second input BJT 160, such that the input circuit 150 could include two input pins, each associated with a separate input BJT and collector connected load. Each of the input BJTs could thus have emitter terminals tied together and connected to the collector terminal of the first input BJT 154.

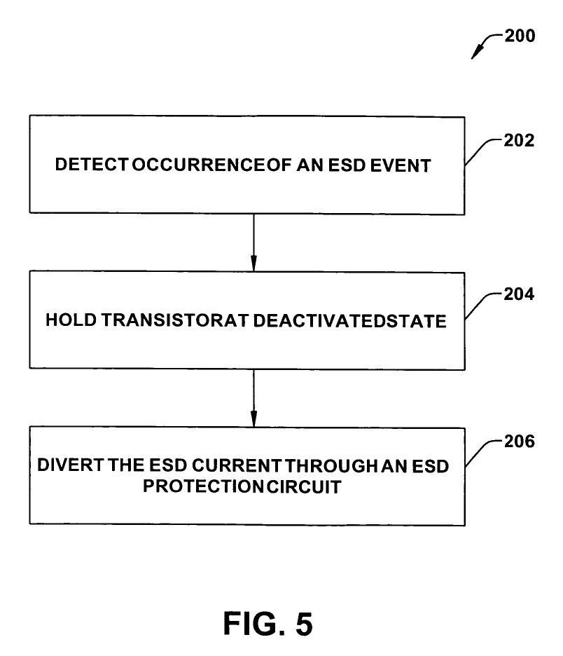

In view of the foregoing structural and functional features described above, certain methods will be better appreciated with reference to FIG. 5. It is to be understood and appreciated that the illustrated actions, in other embodiments, may occur in different orders and/or concurrently with other actions. Moreover, not all illustrated features may be required to implement a method.

FIG. 5 illustrates a method 200 for detecting an ESD event and for protecting an input or an output transistor from damage resulting from the detected ESD event. At 202, the occurrence of an ESD event is detected. The detection could occur from detecting an increase in voltage at a node on which the ESD event occurred, or on a different node that is connected by one or more circuit components to the node on which the ESD event occurred. Upon detecting the ESD event, the input or output transistor is held in a deactivated state in response to the ESD event at 204. The input or output transistor can be held in a deactivated state by, for example, coupling the input or output transistor to ground in the case of an NPN BJT or an N-type FET, or by coupling the input or output transistor to a positive voltage supply in the case of a PNP BJT or a P-type FET. The coupling could occur through the activation of a second transistor resulting from the detected increase in the voltage potential at the node or another connected node on which the ESD event occurred.

At 206, the ESD current is diverted from the input or output transistor through an ESD protection circuit. The diversion could occur due to the input or output transistor being held in a deactivated state, resulting in a higher breakdown voltage than an activation voltage of the ESD protection circuit. This could result in a lower impedance path through the ESD protection circuit, causing a substantial portion of the ESD current to flow through the ESD protection circuit and thus preventing damage to the input or output transistor resulting from the ESD event.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications, and variations that fall within the spirit and scope of the appended claims.

What is claimed is:

1. A system for protecting a transistor from an electrostatic discharge (ESD) current associated with an ESD event, the system comprising:
a detection circuit operative to detect an ESD event;
a switch operative to hold the transistor in a deactivated state in response to the detection circuit detecting the ESD event; and
an ESD protection circuit operative to divert the ESD current from flowing through the transistor upon the transistor being held in a deactivated state.

2. The system of claim 1, wherein, upon the transistor being held in a deactivated state, the transistor has a breakdown voltage that is greater than an activation voltage of the ESD protection circuit, resulting in a substantial portion of the ESD current being diverted through the ESD protection circuit instead of through the transistor.

3. The system of claim 1, wherein the switch holds the transistor in a deactivated state by coupling an input terminal of the transistor to one of a negative voltage supply terminal of the system and a positive voltage supply terminal of the system.

4. The system of claim 1, wherein the transistor comprises a first transistor and the switch comprises a second transistor.

5. The system of claim 4, wherein the detection circuit comprises a capacitor divider interconnected between a positive voltage supply terminal of the system and a negative voltage supply terminal of the system, the capacitor divider being operative to activate the second transistor upon the occurrence of the ESD event to hold the first transistor in the deactivated state.

6. The system of claim 5, wherein the detection circuit further comprises a resistor operative to discharge the capacitor divider after the capacitor divider activates the second transistor to return the system to normal operating conditions.

7. The system of claim 1, wherein the transistor comprises one of a bipolar junction transistor (BJT) and a field effect transistor (FET), and further comprises one of an input device and an output device.

8. The system of claim 1, wherein the ESD protection circuit is connected parallel to the transistor.

9. A power amplifier circuit comprising the system of claim 1.

10. A system for protecting a transistor from electrostatic discharge (ESD) current associated with an ESD event, the system comprising:
means for holding the transistor in a deactivated state upon the occurrence of the ESD event;
means for diverting the ESD current from flowing through the transistor upon the transistor being deactivated; and
means for returning the system to normal operating conditions after the occurrence of the ESD event.

11. The system of claim 10, wherein the transistor has a breakdown voltage that is greater than an activation voltage of the ESD protection circuit upon the transistor being deactivated.

12. The system of claim 10, wherein the transistor comprises one of a bipolar junction transistor (BJT) and a field effect transistor (FET), and further comprises one of an input device and an output device.

13. A method for protecting a transistor from an ESD current associated with an electrostatic discharge (ESD) event, the magnitude comprising:
detecting an ESD event;
holding the transistor in a deactivated state in response to detecting the ESD event; and
diverting the ESD current from flowing through the transistor upon holding the transistor in a deactivated state.

14. The method of claim 13, wherein the diverting the ESD current comprises diverting the ESD current through an ESD protection circuit.

15. The method of claim 13, wherein the diverting the ESD current further comprises setting a breakdown voltage of the transistor greater than an activation voltage of the ESD protection circuit upon holding the transistor in a deactivated state.

16. The method of claim 13, wherein the holding the transistor in a deactivated state comprises coupling an input terminal of the transistor to one of a negative voltage supply terminal of the system and a positive voltage supply terminal of the system.

17. The method of claim 16, wherein the switching the input terminal comprises activating a second transistor to couple the input terminal of the transistor to the negative voltage supply terminal of the system.

18. The method of claim 13, wherein the detecting the ESD event comprises changing a voltage potential of a gate terminal relative to a source terminal of a second transistor upon the occurrence of the ESD event, the changing the voltage potential occurring through a capacitor divider interconnected between a positive voltage supply terminal of the system and a negative voltage supply terminal of the system.

19. The method of claim 18, further comprising discharging the capacitor divider through a resistor after detecting the ESD event.

20. The method of claim 13, wherein the transistor comprises one of a bipolar junction transistor (BJT) and a field effect transistor (FET), and further comprises one of an input device and an output device.
